(19) United States
(12) Patent Application Publication
(10) Pub. No.: US 2025/0227954 A1
(43) Pub. Date: Jul. 10, 2025

(54) POWER SEMICONDUCTOR DEVICES

(71) Applicant: Samsung Electronics Co., Ltd., Suwon-si (KR)

(72) Inventors: Taehun Kim, Suwon-si (KR); Mingu Ko, Suwon-si (KR); Youngcheol Kim, Suwon-si (KR); Jongseob Kim, Suwon-si (KR); Jeongin Noh, Suwon-si (KR); Gyeongseon Park, Suwon-si (KR); Doohyung Cho, Suwon-si (KR); Jeongpyo Hong, Suwon-si (KR)

(21) Appl. No.: 18/783,407

(22) Filed: Jul. 24, 2024

(30) Foreign Application Priority Data
Jan. 9, 2024 (KR) 10-2024-0003621

(51) Int. Cl. H01L 29/78; H01L 29/423

(52) U.S. Cl. CPC H10D 30/668; H10D 64/513; H10D 64/519

(57) ABSTRACT

A power semiconductor device includes a substrate of a first conductivity-type, a drift layer of the first conductivity-type, a well region of a second conductivity-type on the drift layer, a source region of the first conductivity-type on the well region, a gate insulating layer in a gate trench penetrating through the source region and the well region, a gate electrode on the gate insulating layer within the gate trench, a dielectric layer on the gate electrode, a source electrode in contact with the dielectric layer, the well region, and the source region, and a drain electrode on a lower surface of the substrate, wherein a side surface of the dielectric layer is coplanar with a side surface of the gate electrode, and the source region and the well region form a structure that is partially recessed from an upper surface thereof in regions in contact with the source electrode to have inclined surfaces.

### CROSS-REFERENCE TO RELATED APPLICATION(S)

This application claims benefit of priority to Korean Patent Application No. 10-2024-0003621 filed on Jan. 9, 2024 in the Korean Intellectual Property Office, the disclosure of which is incorporated herein by reference in its entirety.

### BACKGROUND

The present inventive concept relates to a power semiconductor device.

Power semiconductor devices are semiconductor devices operating in high voltage and high current environments and have been used in fields requiring high power switching, such as power conversion, power converters, and inverters. Power semiconductor devices generally require an ability to withstand voltage characteristics against high voltages, and recently, often require high-speed switching operations. Accordingly, power semiconductor devices using SiC having superior voltage-withstanding characteristics compared to silicon (Si) have been studied.

### SUMMARY

An aspect of the present inventive concept is to provide a power semiconductor device having improved integration and electrical characteristics.

According to an aspect of the present inventive concept, a power semiconductor device includes a substrate of a first conductivity-type, a drift layer of the first conductivity-type on the substrate, a well region of a second conductivity-type on the drift layer, a source region of the first conductivity-type on the well region, a gate insulating layer in a gate trench penetrating through the source region and the well region, a gate electrode on the gate insulating layer within the gate trench, a dielectric layer on the gate electrode, a source electrode in contact with the dielectric layer, the well region, and the source region, and a drain electrode on a lower surface of the substrate, wherein a side surface of the dielectric layer is coplanar with a side surface of the gate electrode, and the source region and the well region form a structure that is partially recessed from an upper surface thereof in regions in contact with the source electrode to have inclined surfaces.

According to an aspect of the present inventive concept, a power semiconductor device includes a substrate of a first conductivity-type, a drift layer of the first conductivity-type on the substrate, a well region of a second conductivity-type on the drift layer, a source region of the first conductivity-type on the well region, a gate insulating layer in a gate trench penetrating through the source region and the well region, a gate electrode on the gate insulating layer within the gate trench, a dielectric layer on the gate electrode, a source electrode in contact with the dielectric layer, the well region, and the source region, and a drain electrode on a lower surface of the substrate, wherein the source region and the well region include a recess region extending from an upper surface of the source region to the well region through the source region and having inclined sidewalls, and the source electrode fills the recess region.

According to an aspect of the present inventive concept, a power semiconductor device includes a substrate of a first conductivity-type, a drift layer of the first conductivity-type on the substrate, a well region of a second conductivity-type on the drift layer, a source region of the first conductivity-type on the well region, a gate insulating layer in a gate trench penetrating through the source region and the well region, a gate electrode on the gate insulating layer within the gate trench, a dielectric layer on the gate electrode, a source electrode in contact with the dielectric layer, the well region, and the source region, and a drain electrode on a lower surface of the substrate, wherein the source region, the well region, and the dielectric layer have inclined surfaces in a region in contact with the source electrode.

### BRIEF DESCRIPTION OF DRAWINGS

The above and other aspects, features, and advantages of the present inventive concept will be more clearly understood from the following detailed description, taken in conjunction with the accompanying drawings, in which:

FIGS. 1A and 1B are a cross-sectional view and a partially enlarged view respectively illustrating a power semiconductor device according to embodiments;

FIGS. 2A to 2C are cross-sectional views illustrating power semiconductor devices according to embodiments;

FIGS. 3A to 3C are cross-sectional views illustrating power semiconductor devices according to embodiments; and

FIGS. 4A to 4G are diagrams illustrating a sequential process of a method of manufacturing a power semiconductor device according to embodiments.

### DETAILED DESCRIPTION

Hereinafter, embodiments of the present inventive concept are described with reference to the accompanying drawings. Hereinafter, terms, such as ‘top,’ ‘upper,’ ‘upper surface,’ ‘bottom, ‘lower,’ ‘lower surface,’ ‘side surface,’ etc. may be understood as being referred to based on the drawings, unless otherwise specified.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

Items described in the singular herein may be provided in plural, as can be seen, for example, in the drawings. Thus, the description of a single item that is provided in plural should be understood to be applicable to the remaining plurality of items unless context indicates otherwise.

Terms such as “same,” “equal,” “planar,” “coplanar,” “flat,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

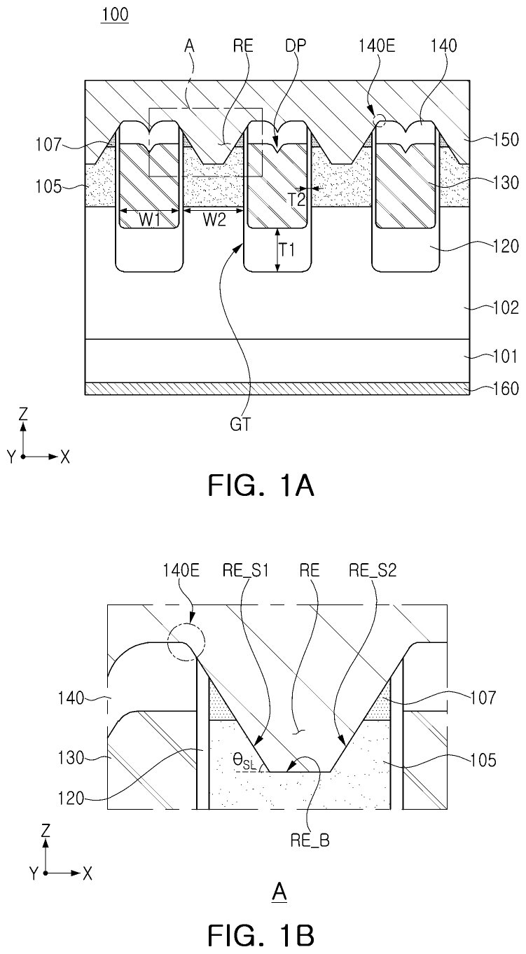

FIGS. 1A and 1B are a cross-sectional view and a partially enlarged view illustrating power semiconductor devices according to embodiments. FIG. 1B is an enlarged view of region ‘A’ of FIG. 1A.

Referring to FIGS. 1A and 1B, a power semiconductor device 100 may include a substrate 101, a drift layer 102 on the substrate 101, well regions 105 on the drift layer 102, source regions 107 on the well regions 105, gate insulating layers 120 in gate trenches GT penetrating through the source regions 107 and the well regions 105, gate electrodes 130 disposed on the gate insulating layers 120 within the gate trenches GT, dielectric layers 140 on the gate electrodes 130, a source electrode 150 disposed on the dielectric layers 140 and filling recess regions RE of the well regions 105 and the source regions 107, and a drain electrode 160 on a lower surface of the substrate 101.

The substrate 101 may have an upper surface extending in X- and Y-directions. The substrate 101 may include a semiconductor material, for example, silicon carbide (SiC). However, in some embodiments, the substrate 101 may also or alternatively include a group IV semiconductor material, such as silicon (Si) or germanium (Ge), or a compound semiconductor material, such as silicon-germanium (SiGe), gallium arsenide (GaAs), indium arsenide (InAs), or indium phosphide (InP).

The substrate 101 may be provided as a bulk wafer or an epitaxial layer. The substrate 101 may include first conductivity-type impurities and thus may have a first conductivity-type. In some embodiments, the first conductivity-type may be, for example, N-type, and the first conductivity-type impurities may be N-type impurities, for example, nitrogen (N) and/or phosphorus (P). In some embodiments, the first conductivity-type may be, for example, P-type, and the first conductivity-type impurities may be, for example, P-type impurities, such as aluminum (Al).

The drift layer 102 may be disposed on the substrate 101. The drift layer 102 may include a semiconductor material, for example, SiC. The drift layer 102 may be an epitaxial layer grown on the substrate 101. The drift layer 102 may include first conductivity-type impurities and thus may have the first conductivity-type. Both the drift layer 102 and the substrate 101 may include the first conductivity-type impurities, and the concentration of the first conductivity-type impurities in the drift layer 102 may be lower than the concentration of the first conductivity-type impurities in the substrate 101. In embodiments, the first conductivity-type impurities in the substrate 101 and the drift layer 102 may be or include the same or different elements (e.g., chemical elements).

In semiconductor technology, if a silicon sample contains both p-type and n-type impurities, the conductivity-type of the silicon will be determined by which type of impurities is in greater concentration. Therefore, if a silicon sample has both p-type and n-type impurities, the net conductivity type will be determined by the dominant impurity concentration. As used herein, a “first conductivity-type” of a component denotes that the dominant impurities are a first conductivity-type impurity, and a doping concentration refers the net concentration of the dominant impurities (i.e., first conductivity-type impurities). The well regions 105 may be regions of the drift layer 102, and may extend to a predetermined depth from an upper surface of the drift layer 102. The well regions 105 may be arranged to be spaced apart from each other by the gate trenches GT in a horizontal direction, for example, the X-direction. Each well region 105, also described as a well, may include a semiconductor material, for example, SiC. The well region 105 may be a region having a second conductivity-type and may include second conductivity-type impurities. For example, the second conductivity-type may be P-type, and the second conductivity-type impurities may be P-type impurities, such as aluminum (Al). In some embodiments, each well region 105 may include a plurality of regions having different doping concentrations. For example, in some embodiments, a region exposed through the recess region RE in the well region 105 may have a higher doping concentration than other regions.

The source regions 107, which may be part of the well regions 105, may extend to a predetermined depth from the upper surfaces of the well regions 105. The thickness of the source region 107 may be less than the thickness of the well region 105, with the thickness referring to a thickness in the vertical direction (Z direction). The source region 107 may include a semiconductor material, for example, SiC. The source region 107 may be a region having the first conductivity-type and may include the first conductivity-type impurities described above. The concentration of the first conductivity-type impurities of the source region 107 may be higher than the concentration of the first conductivity-type impurities of the drift layer 102 but is not limited thereto.

The combined well regions 105 and source regions 107 may include recess regions RE penetrating through the source regions 107 from the upper surfaces of the source regions 107 and recessing the well regions 105. The gate insulating layers 120 and the dielectric layer 140 may also be partially removed in the process of forming the recess regions RE.

The source region 107 may be separated by the recess region RE penetrating between adjacent gate trenches GT and may be exposed through sidewalls RE_S1 and RE_S2 of the recess region RE. The well region 105 is removed from an upper surface thereof to a predetermined depth by the formation of the recess region RE and may be exposed through the sidewalls RE_S1 and RE_S2 and a bottom surface RE_B of the recess region RE. The recess region RE will be described in more detail below with reference to FIG. 1B.

The gate trenches GT may extend from the upper surfaces of the source regions 107 into the drift layer 102 through the source regions 107 and the well regions 105. The gate trenches GT may be spaced apart from each other in the X-direction and may extend in the Y-direction. Each gate trench GT may completely penetrate through the well region 105, and a lower end of the gate trench GT may be located within the drift layer 102. However, the length of the gate trench GT extending into the drift layer 102 and the degree of bending of a lower surface thereof may vary in various embodiments. The gate insulating layer 120, the gate electrode 130, and at least a portion of the dielectric layer 140 may be disposed in the gate trench GT.

The gate insulating layers 120 may be respectively disposed within the gate trenches GT. Each gate insulating layer 120 may extend along the bottom surface and sidewalls of a respective gate trench GT and may cover the side and lower surfaces of a respective gate electrode 130. The gate insulating layer 120 may be disposed between the source region 107, the well region 105, and the drift layer 102 and the gate electrode 130. Upper ends (e.g., a top-most portion) of the gate insulating layer 120 may be located at a higher level than an upper end (e.g., a top-most portion) of the gate electrode 130, but are not limited thereto.

The gate insulating layer 120 may have a nonuniform thickness. The gate insulating layer 120 may have a first thickness T1 on the bottom surface of the gate trench GT and a second thickness T2 that is less than the first thickness T1 on the sidewalls of the gate trench GT. In this manner, the thickness of these portions is measured in a direction perpendicular to a surface on which the portion is formed. The first thickness T1 may be, for example, greater than 2 times the second thickness T2 and less than 10 times the second thickness T2, and in some embodiments may be between 3 and 7 times the second thickness T2. Since the gate insulating layer 120 has a relatively large thickness on the bottom surface of the gate trench GT, even if the pitch of the gate electrodes 130 is reduced, an electric field formed in the drift layer 102 by the gate electrode 130 may be alleviated, thereby preventing breakdown of the gate insulating layer 120.

The gate insulating layer 120 may include oxide, nitride, or a high-k material. The high-k material may refer to a dielectric material having a higher dielectric constant than a silicon dioxide (SiO₂). The high-k material may be, for example, any one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃).

The gate electrodes 130 may be respectively disposed within the gate trenches GT, extend in the Y-direction, and be spaced apart from each other in the X-direction. Each gate electrode 130 may be disposed on a respective gate insulating layer 120 within the gate trench GT. The gate electrode 130 may overlap the drift layer 102, the well region 105, and the source region 107 in the horizontal direction, for example, the X-direction. A lower surface (e.g., bottom, or lowermost surface) of the gate electrode 130 may be located within the drift layer 102. In some embodiments, the lower surface (e.g., bottom, or lowermost surface) of the gate electrode 130 may be located within the well region 105.

The lower surface of the gate electrode 130 may be located at the same level as a lower surface of the well region 105 or at a lower level. An upper surface of the gate electrode 130 may be located at a lower level than an upper surface of the source region 107 and may be located at the same level as an upper surface of the well region 105 or at a higher level. For example, the upper surface of the gate electrode 130 may be located at a level between the upper and lower surfaces of the source region 107. The various levels discussed herein refer to heights or distances, in the vertical direction (Z direction) from a top surface of the substrate 101. The gate electrode 130 may have a depression DP on an upper surface thereof that is depressed downwardly toward the substrate 101. However, in embodiments, the presence/absence, shape, depth, etc. of the depression DP may vary.

The gate electrode 130 may have a first width W1 in the X-direction, and a gap between adjacent gate trenches GT may have a second width W2. The first width W1 may be less than or equal to the second width W2. The first width W1 and the second width W2 may each have a value in a range from about 0.4 μm to about 0.6 μm. For example, the pitch, that is, a sum of the first width W1 of the gate electrodes 130 and a distance between the gate electrodes 130 may have a value in a range from about 0.8 μm to about 1.2 μm.

The gate electrode 130 may include a conductive material, for example, a semiconductor material, such as doped polycrystalline silicon, a metal nitride, such as titanium nitride film (TiN), tantalum nitride film (TaN), or tungsten nitride film (WN), and/or a metal material, such as aluminum (Al), tungsten (W), or molybdenum (Mo). According to embodiments, the gate electrode 130 may include two or more layers.

The dielectric layers 140 may cover the gate electrodes 130 and may be disposed to expose portions of the source regions 107 and well regions 105. The dielectric layer 140 may fill part of the gate trench GT and cover the upper surface of the gate electrode 130. The dielectric layer 140 may be disposed only on the gate electrode 130 and may entirely overlap the gate electrode 130 in a vertical direction, for example, a Z-direction. Side surfaces of the dielectric layer 140 may be coplanar with side surfaces of the gate electrode 130. The dielectric layer 140 may not cover an upper end (e.g., upward-facing surface) of the gate insulating layer 120. The dielectric layer 140 may be spaced apart from the source region 107 by the gate insulating layer 120, and an upper end (e.g., top-most portion or surface) of the dielectric layer 140 may be located at a higher level than an upper end (e.g., top-most portion or surface) of the source region 107. The dielectric layer 140 may have a depression corresponding to the depression DP of the gate electrode 130 on an upper surface thereof. The dielectric layer 140 may include an insulating material and may include at least one of silicon oxide, silicon nitride, and silicon oxynitride.

As shown in FIG. 1B, the well region 105, the source region 107, the gate insulating layer 120, and the dielectric layer 140 may each have an inclined surface in the recess region RE in contact with the source electrode 150. The inclined surfaces may be coplanar with each other. The recess region RE may have inclined sidewalls RE_S1 and RE_S2 and a bottom surface RE_B between the sidewalls RE_S1 and RE_S2.

The sidewalls RE_S1 and RE_S2 of the recess region RE may be inclined at a slope angle θ_{SL} with respect to the upper surface of the substrate 101. The slope angle θ_{SL} may be about 87 degrees or less based on the upper surface of the substrate 101 and may be in a range, for example, from about 50 degrees to about 87 degrees. In some embodiments, the slope angle θ_{SL} may be 70 degrees or less, for example, in the range of about 50 degrees to about 70 degrees. The bottom surface RE_B of the recess region RE may connect the sidewalls RE_S1 and RE_S2 and may extend substantially flat.

The source region 107 may have a shape having a width decreasing upwardly. For example, the source region 107 may have a triangular or similar shape in a cross-sectional view. In the well region 105, three surfaces connected to each other may be exposed through the recess region RE. The well region 105 and the source region 107 may have a substantially uniform slope at the sidewalls RE_S1 and RE_S2 of the recess region RE, and the slope may extend substantially uniformly from at least a portion of an edge region 140E of the dielectric layer 140. Due to the slope, the surfaces of the well region 105 and the source region 107 may have a straight shape in the cross-sectional view.

The edge region 140E may include a slope region, which may be connected to the inclined surfaces of well region 105 and source region 107. The slope region may start from a location, from a top-down view, above the gate electrode 130 and inside the side surfaces of the gate electrode 130, for example, from inside the gate trench GT. In the present embodiment, the degree of slope, or the slope angle of the slope region may be substantially the same as those of the adjacent gate insulating layer 120 or those of the well region 105 and the source region 107. The gate insulating layer 120 may also have an inclined surface, and the inclined surface of the slope region, the inclined surface of the gate insulating layer 120, the inclined surface of the well region 105, and the inclined surface of the source region 107 may be sequentially connected (e.g., to be coplanar and form a continuous surface with no steps or breaks between portions).

However, the edge region 140E of the dielectric layer 140 may be partially removed during the manufacturing process and have a rounded corner, and a specific shape of the rounded region may vary in various embodiments. For example, in some embodiments, the edge region 140E of the dielectric layer 140 may be partially removed to have a gentle shape, in which case the slopes of the inclined surfaces of the well region 105 and the source region 107 may not be continuous up to the dielectric layer 140.

In the power semiconductor device 100, the dielectric layer 140 and the recess region RE may be formed by a selective etching process, rather than a photolithography process. Accordingly, the pitch of the gate electrodes 130 may be minimized, and since the source electrode 150 contacts the source region 107 and the well region 105 through the sloped sidewalls RE_S1 and RE_S2, a contact area may increase and contact resistance may be lowered.

The source electrode 150 may be disposed on the dielectric layer 140, the source regions 107, and the well regions 105, and may be electrically connected to the source regions 107 and the well regions 105. The source electrode 150 may fill the recess regions RE of the source regions 107 and well regions 105 and may contact the source regions 107 and the well regions 105 in the recess regions RE. A lower end (e.g., bottom-most portion or surface) of the source electrode 150 may be located at a lower level than the lower surface (e.g., bottom-most surface) of the source region 107, the upper surface of the well region 105, and the upper surface of the gate electrode 130.

The source electrode 150 may include a metal material, for example, at least one of nickel (Ni), aluminum (Al), titanium (Ti), silver (Ag), vanadium (V), tungsten (W), cobalt (Co), molybdenum (Mo), copper (Cu), and ruthenium (Ru). The source electrode 150 may include a metal-semiconductor compound layer disposed at an interface in contact with the source regions 107 and the well regions 105. The metal-semiconductor compound layer may include a metal element and a semiconductor element and may include, for example, at least one of TiSi, CoSi, MoSi, LaSi, NiSi, TaSi, or Wsi.

The drain electrode 160 may be disposed on the lower surface of the substrate 101 and may be electrically connected to the substrate 101. The drain electrode 160 may include a metal material, for example, at least one of nickel (Ni), aluminum (Al), titanium (Ti), silver (Ag), vanadium (V), and tungsten (W). In some embodiments, the drain electrode 160 may also include a metal-semiconductor compound layer similar to the source electrode 150.

The power semiconductor device 100 has been described as an example in the form of a metal oxide semiconductor field effect transistor (MOSFET), but the structure of the recess region RE, dielectric layer 140, and source electrode 150 in the embodiments may also be applied to a super junction MOSFET, a double trench MOSFET, an insulated gate bipolar transistor (IGBT) device, and the like. For example, when the power semiconductor device is an IGBT, the substrate 101 may have the second conductivity-type.

In the descriptions of the following embodiments, descriptions that overlap those given above with reference to FIGS. 1A and 1B are omitted.

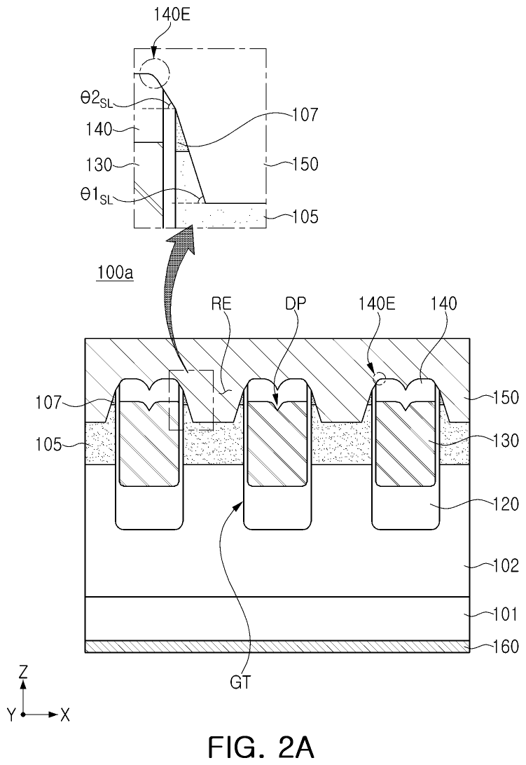

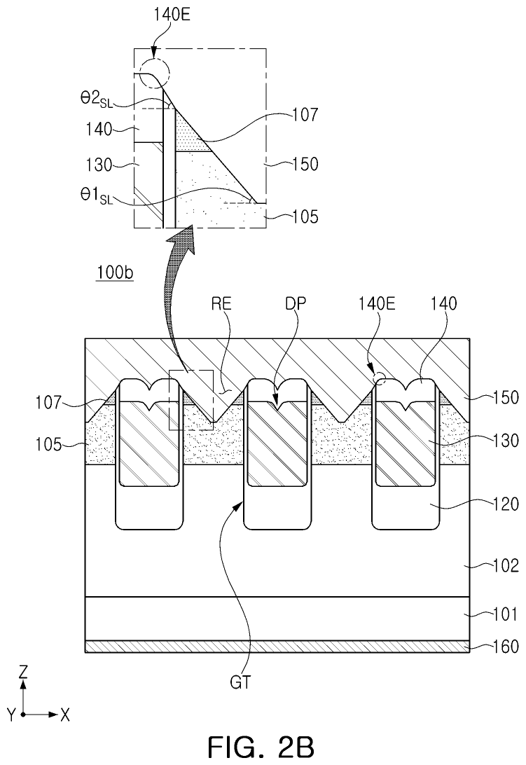

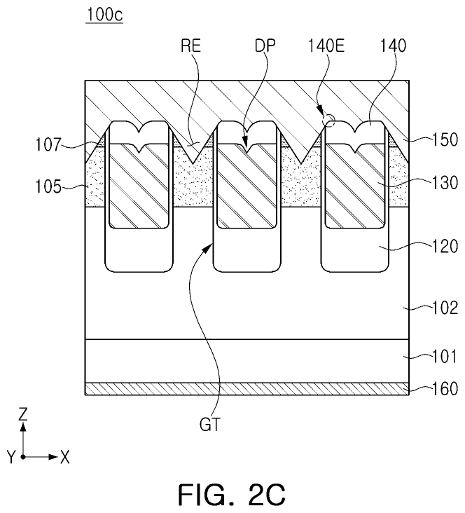

FIGS. 2A to 2C are cross-sectional views illustrating power semiconductor devices according to embodiments.

Referring to FIG. 2A, in a power semiconductor device 100a, a first slope angle θ1_{SL} of the inclined surfaces of the well region 105 and the source region 107 exposed through the recess region RE may be different from a second slope angle θ2_{SL} of the inclined surfaces of the dielectric layer 140 and the gate insulating layer 120. In the present embodiment, the first slope angle θ1_{SL} may be greater than the second slope angle θ2_{SL}.

Since the well region 105 and the source region 107 are based on the same material, for example, SiC, the well region 105 and the source region 107 may be etched at the same or similar etch rate when forming the recess region RE and may have substantially the same slope. When the dielectric layer 140 and the gate insulating layer 120 are also based on the same material, for example, silicon oxide, the dielectric layer 140 and the gate insulating layer 120 may be etched at the same or similar etch rate when forming the recess region RE and may have substantially the same slope. However, in some embodiments, the dielectric layer 140 is also etched from the upper surface thereof, so the slope angle of the inclined surface of the dielectric layer 140 and the slope angle of the inclined surface of the gate insulating layer 120 may be different from each other.

Referring to FIG. 2B, in a power semiconductor device 100b, the first slope angle θ1_{SL} of the inclined surfaces of the well region 105 and the source region 107 exposed through the recess region RE may be less than the second slope angle θ2_{SL} of the inclined surfaces of the dielectric layer 140 and the gate insulating layer 120. Accordingly, the bottom surface of the recess region RE may have a relatively narrow width. In some embodiments, the slope angle of the inclined surface of the dielectric layer 140 may also be different from the slope angle of the inclined surface of the gate insulating layer 120.

Referring to FIG. 2C, in the power semiconductor device 100c, the inclined sidewalls RE_S1 and RE_S2 of the recess region RE may be directly connected to each other. In the present embodiment, the recess region RE may not have a horizontally extending bottom surface RE_B (see FIG. 1B).

As illustrated in FIGS. 2A to 2C, in embodiments, a relative size of the degree of slope of the inclined surfaces of well region 105 and source region 107 and the degree of slope of the inclined surfaces of dielectric layer 140 and gate insulating layer 120 may vary.

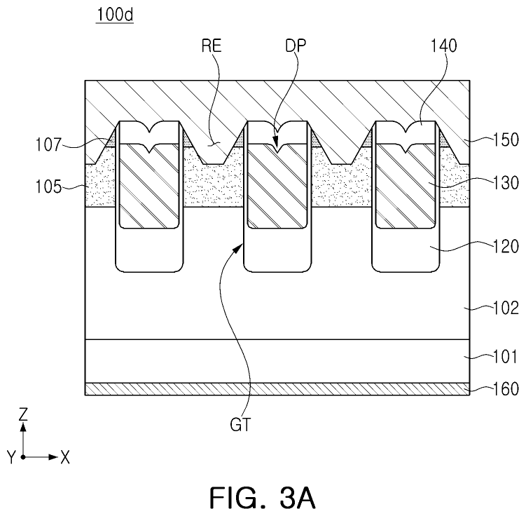

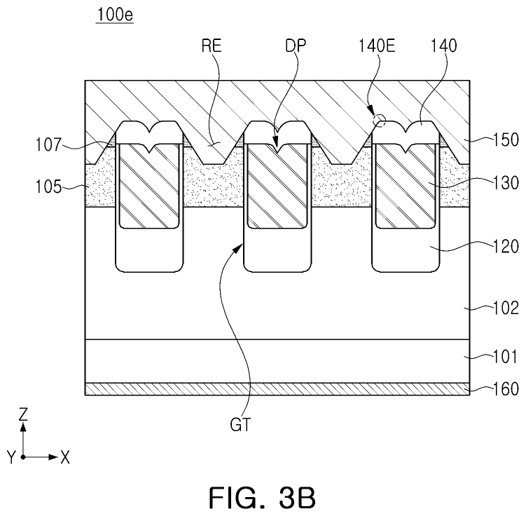

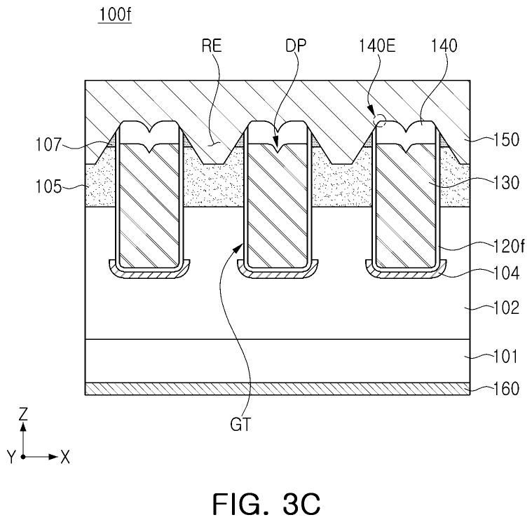

FIGS. 3A to 3C are cross-sectional views illustrating power semiconductor devices according to embodiments.

Referring to FIG. 3A, in a power semiconductor device 100d, the dielectric layer 140 may not be recessed by the recess region RE. Accordingly, the slope of the surfaces of the well region 105 and the source region 107 may extend only up to the gate insulating layer 120. This shape may be due to etch selectivity, degree of etching, or the like, during the process of forming the recess region RE. In some embodiments, the slope of the surfaces of well region 105 and source region 107 may extend only to a portion of gate insulating layer 120 or may not extend to the gate insulating layer 120 as well.

Referring to FIG. 3B, in a power semiconductor device 100e, a position of an upper end of the gate insulating layer 120 may be substantially the same as the level of the upper surface of the gate electrode 130. In the present embodiment, the upper end of the gate insulating layer 120 may be located relatively low compared to the embodiment of FIGS. 1A and 1B, and the upper surface of the gate insulating layer 120 may be covered with the dielectric layer 140.

Referring to FIG. 3C, in a power semiconductor device 100f, the gate insulating layer 120f may have a substantially uniform thickness within the gate trench GT, and the power semiconductor device 100f may further include field relaxation regions 104.

The field relaxation regions 104 may be disposed along a portion of an outer surface of each of the gate trenches GT and may cover the portion of the outer surface. The field relaxation region 104 may be located within the drift layer 102 below the gate electrode 130 and may be located between the gate insulating layer 120 and the drift layer 102.

The field relaxation region 104 may include a semiconductor material, for example, SiC. The field relaxation region 104 may be a doped region formed by doping a portion of the drift layer 102. The field relaxation region 104 may be a region having the same conductivity-type as that of the well region 105, for example, the second conductivity-type, and may include the second conductivity-type impurities. The concentration of the second conductivity-type impurities of the field relaxation region 104 may be higher than the concentration of the second conductivity-type impurities in the well region 105. By the field relaxation region 104, an electric field formed in the drift layer 102 by the gate electrode 130 may be alleviated, and thus, breakdown of the gate insulating layer 120 may be prevented.

In some embodiments, the gate insulating layer 120f of the power semiconductor device may include the field relaxation region 104 as in the present embodiment, while having a relatively great thickness from the bottom surface of the gate trench GT as illustrated in FIG. 1A.

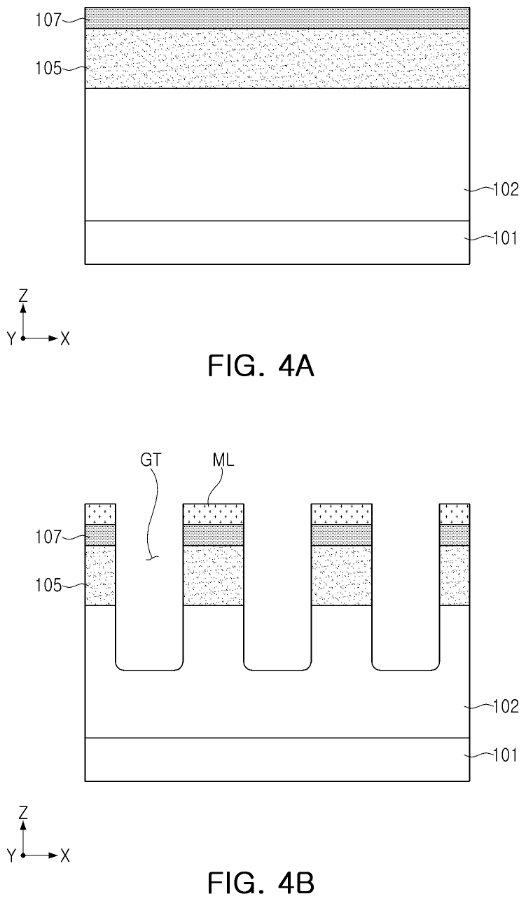

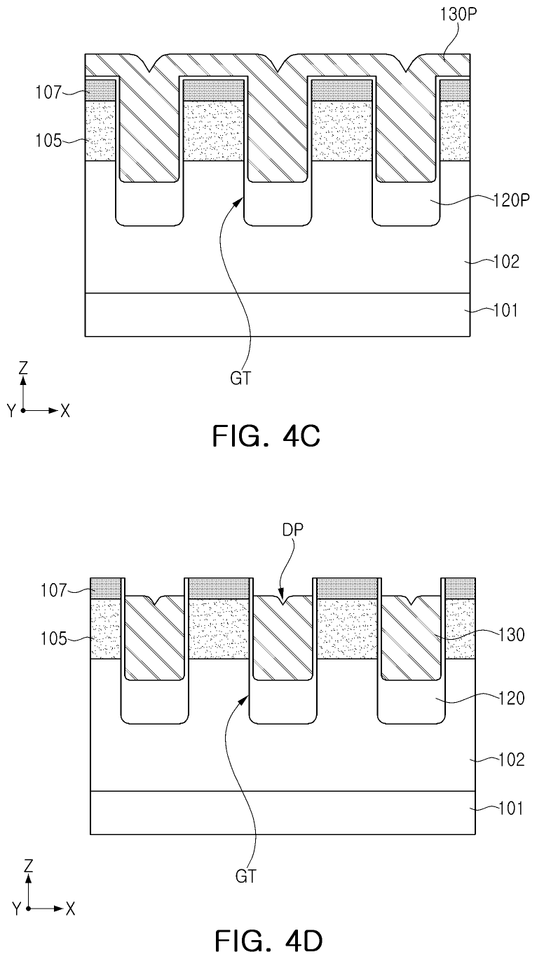

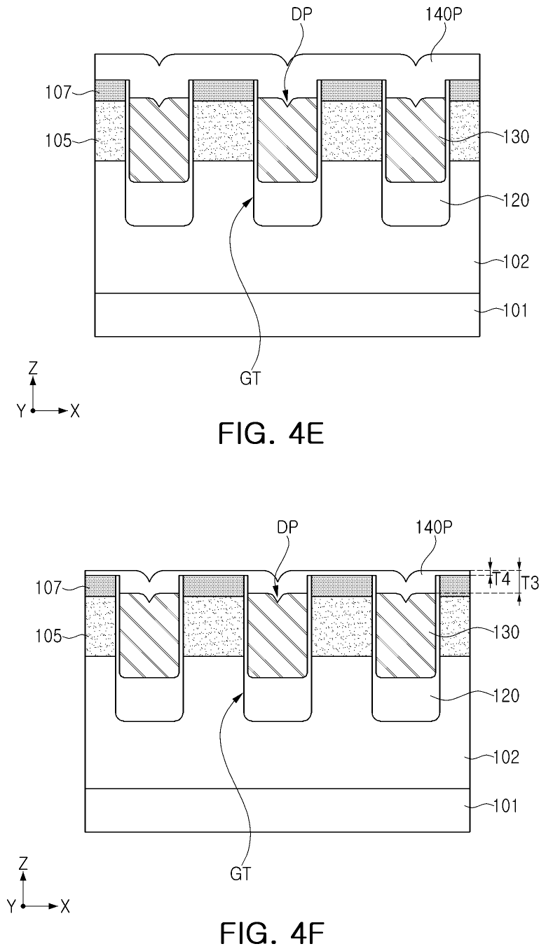

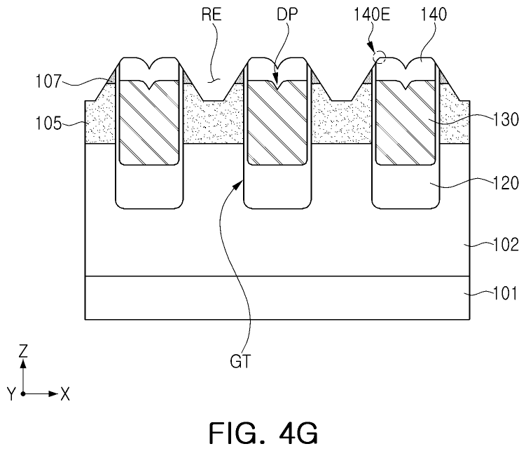

FIGS. 4A to 4G are diagrams illustrating a sequential process of a method of manufacturing a power semiconductor device according to embodiments. An embodiment of a method of manufacturing the power semiconductor device of FIG. 1A is described with reference to FIGS. 4A to 4G.

Referring to FIG. 4A, the drift layer 102 may be formed on the substrate 101, and the well region 105 and the source region 107 may be formed.

The substrate 101 may be provided as a SiC wafer, for example. The drift layer 102 may be epitaxially grown from the substrate 101 to be formed. The drift layer 102 may be formed to include first conductivity-type impurities.

The well region 105 and the source region 107 may be sequentially formed in the drift layer 102 by an ion implantation process. Second conductivity-type impurities may be implanted into the well region 105, and first conductivity-type impurities may be implanted into the source region 107. After the ion implantation process, an annealing process may be performed at high temperatures of, for example, about 1600° C. to about 1800° C.

Referring to FIG. 4B, the gate trenches GT may be formed.

The gate trenches GT may be formed by partially removing the source region 107, the well region 105, and the drift layer 102 using a mask layer ML. The mask layer ML may be, for example, a hard mask layer. The gate trenches GT may be formed to be spaced apart from each other in the horizontal direction, for example, the X-direction. The gate trenches GT may be formed to penetrate through the source region 107 and the well region 105, and the drift layer 102 may be exposed through the bottom surface. In some embodiments, the gate trench GT may have a bottom surface that is rounder than shown.

Referring to FIG. 4C, a preliminary gate insulating layer 120P and a preliminary gate electrode 130P may be formed.

The preliminary gate insulating layer 120P may be formed by first forming a uniform first insulating layer through an oxidation process, for example, a thermal oxidation process and then forming a second insulating layer through a spin-on glass (SOG) process or a high temperature oxide (HTO) process. Alternatively, the preliminary gate insulating layer 120P may be formed by forming an insulating layer to fill the gate trenches GT and then partially removing the insulating layer. The preliminary gate insulating layer 120P may be formed thicker on the bottom surfaces of the gate trenches GT than on the sidewalls of the gate trenches GT.

Next, a conductive material may be deposited to form a preliminary gate electrode 130P filling the gate trenches GT. The preliminary gate electrode 130P may include, for example, doped polycrystalline silicon or a metal material.

Referring to FIG. 4D, the gate insulating layers 120 and the gate electrodes 130 may be formed by partially removing the preliminary gate insulating layer 120P and the preliminary gate electrode 130P.

The gate insulating layers 120 and gate electrodes 130 may be formed to be located only within the gate trenches GT by, for example, performing an etch-back process. The gate electrodes 130 may have depressions DP on upper surfaces thereof depending on the aspect ratio of the gate trenches GT and deposition conditions of the gate electrodes 130. However, in some embodiments, the upper surfaces of the gate electrodes 130 may be flat.

Referring to FIG. 4E, a preliminary dielectric layer 140P may be formed.

The preliminary dielectric layer 140P may be formed by depositing an insulating material on the entire upper surface of the structure being manufactured. The preliminary dielectric layer 140P may cover the gate electrodes 130, may fill the gate trenches GT, may extend onto the source regions 107, and may be formed to have a relatively large thickness.

Referring to FIG. 4F, a portion of the preliminary dielectric layer 140P may be removed.

The preliminary dielectric layer 140P may be partially removed to remain at a relatively small thickness on the source regions 107, while filling the gate trenches GT by performing, for example, an etch-back process. The preliminary dielectric layer 140P may be formed to have a third thickness T3 on the gate electrodes 130 and a fourth thickness T4 that is less than the third thickness T3 on the source regions 107. The third thickness T3 may be twice or more the fourth thickness T4.

Referring to FIG. 4G, the recess regions RE may be formed by partially removing the preliminary dielectric layer 140P, source regions 107, and well regions 105.

The recess regions RE may be formed by an etching process, for example, a dry etching process. The etching process may be performed by adjusting an etch rate of the source regions 107 and the well regions 105 to be higher than an etch rate of the preliminary dielectric layer 140P. The etching process may be performed by adjusting relative etch selectivity of a semiconductor material forming the source regions 107 and the well regions 105, such as SiC, and an insulating material forming the preliminary dielectric layer 140P, such as SiO₂. For example, the etch rate of SiC:SiO₂ may be adjusted to be about 3:1 or more, for example, in the range of about 2.5:1 to about 3.5:1. Accordingly, the depth at which the source regions 107 and the well regions 105 are etched may be greater than the depth at which the preliminary dielectric layer 140P is etched. The etching process may be performed using, for example, an etchant including SF₆ and oxygen (O₂) gas. As a result, the dielectric layers 140 separated from each other may be formed between the gate trenches GT, together with the recess regions RE.

The recess regions RE have inclined sidewalls extending from the edge regions 140E of the dielectric layers 140 to the gate insulating layers 120, source regions 107, and well regions 105.

Thereafter, referring to FIG. 1A together, the source electrode 150 may be formed to fill the recess regions RE and cover the dielectric layers 140, and the drain electrode 160 may be formed on the lower surface of the substrate 101. Since the source electrode 150 is deposited to be formed along the gentle slope of the dielectric layers 140, source region 107, and well region 105, internal stress may be reduced. In some embodiments, the drain electrode 160 may be formed in another process stage. As a result, the power semiconductor device 100 of FIG. 1A may be manufactured.

The power semiconductor device having improved integration and electrical characteristics improved by including the self-aligned source electrode may be provided.

While embodiments have been shown and described above, it will be apparent to those skilled in the art that modifications and variations could be made without departing from the scope of the present invention as defined by the appended claims.

What is claimed is:

1. A power semiconductor device comprising:
a substrate of a first conductivity-type;
a drift layer of the first conductivity-type on the substrate;
a well region of a second conductivity-type on the drift layer;
a source region of the first conductivity-type on the well region;
a gate insulating layer in a gate trench penetrating through the source region and the well region;
a gate electrode on the gate insulating layer within the gate trench;
a dielectric layer on the gate electrode;
a source electrode in contact with the dielectric layer, the well region, and the source region; and
a drain electrode on a lower surface of the substrate,
wherein a side surface of the dielectric layer is coplanar with a side surface of the gate electrode, and
wherein the source region and the well region form a structure that is partially recessed from an upper surface thereof in regions in contact with the source electrode to have inclined surfaces.

2. The power semiconductor device of claim 1, wherein:
the dielectric layer includes a slope region in an edge region adjacent to the source region, and
the inclined surfaces of the source region and the well region are connected to the slope region of the dielectric layer.

3. The power semiconductor device of claim 2, wherein the slope region has a first slope angle, and the inclined surfaces of the source region and the well region have a second slope angle, different from the first slope angle.

4. The power semiconductor device of claim 2, wherein, in a cross-section, the edge region has a rounded shape and the inclined surfaces of the source region and the well region have a straight shape.

5. The power semiconductor device of claim 2, wherein the gate insulating layer has a slope connected to the slope region and the inclined surfaces of the source region and the well region between the dielectric layer and the source region.

6. The power semiconductor device of claim 1, wherein a slope angle of the inclined surfaces of the source region and the well region is a slope angle in a range from about 50 degrees to about 87 degrees with respect to an upper surface of the substrate.

7. The power semiconductor device of claim 1, wherein a top-most surface of the gate electrode is at a lower level than a top-most surface of the source region.

8. The power semiconductor device of claim 1, wherein a bottom-most portion of the source electrode is at a lower level than a top-most surface of the well region.

9. The power semiconductor device of claim 1, wherein a bottom-most portion of the source electrode is at a lower level than a top-most surface of the gate electrode.

10. The power semiconductor device of claim 1, wherein a top-most portion of the dielectric layer is at a higher level than top-most portion of the source region.

11. The power semiconductor device of claim 1, wherein the gate electrode and the dielectric layer each have a depression depressed downwardly from upper surfaces thereof.

12. The power semiconductor device of claim 1, wherein the gate insulating layer has a first thickness on a bottom surface of the gate trench and has a second thickness less than the first thickness on sidewalls of the gate trench.

13. The power semiconductor device of claim 1, wherein the substrate, the drift layer, and the well region include SiC.

14. A power semiconductor device comprising:
a substrate of a first conductivity-type;
a drift layer of the first conductivity-type on the substrate;
a well region of a second conductivity-type on the drift layer;
a source region of the first conductivity-type on the well region;
a gate insulating layer in a gate trench penetrating through the source region and the well region;
a gate electrode on the gate insulating layer within the gate trench;
a dielectric layer on the gate electrode;
a source electrode in contact with the dielectric layer, the well region, and the source region; and
a drain electrode on a lower surface of the substrate,
wherein the source region and the well region include a recess region extending from an upper surface of the source region to the well region through the source region and having inclined sidewalls, and
wherein the source electrode fills the recess region.

15. The power semiconductor device of claim 14, wherein the recess region further includes a bottom surface connecting the sidewalls.

16. The power semiconductor device of claim 15, wherein:
the source region and the well region contact the source electrode through the sidewalls of the recess region, and
the well region contacts the source electrode through the bottom surface of the recess region.

17. The power semiconductor device of claim 14, wherein the source region is spaced apart from the dielectric layer.

18. The power semiconductor device of claim 14, wherein the sidewalls of the recess region are directly connected to each other.

19. A power semiconductor device comprising:
a substrate of a first conductivity-type;
a drift layer of the first conductivity-type on the substrate;
a well region of a second conductivity-type on the drift layer;
a source region of the first conductivity-type on the well region;
a gate insulating layer in a gate trench penetrating through the source region and the well region;
a gate electrode on the gate insulating layer within the gate trench;
a dielectric layer on the gate electrode;
a source electrode in contact with the dielectric layer, the well region, and the source region; and
a drain electrode on a lower surface of the substrate,
wherein the source region, the well region, and the dielectric layer have inclined surfaces in a region in contact with the source electrode.

20. The power semiconductor device of claim 19, wherein the dielectric layer is disposed to entirely overlap the gate electrode in a vertical direction.
